(19) United States
(12) Patent Application Publication
(10) Pub. No.: US 2004/0252856 A1
(43) Pub. Date: Dec. 16, 2004

(54) Bass loudspeaker apparatus and multiway loudspeaker system having the same

(76) Inventor: Tadashi Masuda, Iwakura-shi (JP)

Correspondence Address: DARBY & DARBY P.C., P. O. BOX 5257, NEW YORK, NY, 10150-5257, US

(21) Appl. No.: 10/816,608

(22) Filed: Apr. 2, 2004

(30) Foreign Application Priority Data
Jun. 12, 2003 (JP) 2003-167354

(51) Int. Cl. H05K 5/00; H04R 1/02; H04R 1/20

(52) U.S. Cl. 381/340; 381/345; 381/351

(57) ABSTRACT

A bass loudspeaker apparatus capable of according with a horn-type midbass in both the appearance and acoustics is disclosed. A bass loudspeaker apparatus A is provided with a cabinet 70 having an inner space 75 and a sound emission opening 71 in a front section; a corn-type woofer 3 disposed within the cabinet 70; a baffle plate 2 having a woofer mounting section 72 and vertically disposed in the inner space 75 so as to face the sound emission opening 71; a resonant chamber 73 defined in front of the baffle plate 2 for communicating with the sound emission opening 71. The front ends of the loudspeaker apparatuses A and 80 are approximately aligned in the state that the sound source position of the bass loudspeaker apparatus A is aligned with that of the horn-type midbass 80. Thus, the uniformity in the appearance is secured. The resonant chamber 73 and the sound emission opening 71 are respectively designed such that resonance occurs between an air mass around the periphery of the sound emission opening 71 and an air spring within the resonant chamber 73 at a predetermined frequency range of 150 through 400 Hz. Therefore, the distortion in the frequency characteristic produced in the resonant chamber 73 can be easily corrected.

### BACKGROUND OF THE INVENTION

1. Field of the Invention

The present invention relates to a bass loudspeaker apparatus for constituting a multiway loudspeaker system and the multiway loudspeaker system having the bass loudspeaker apparatus.

2. Description of the Prior Art

A horn used in a horn-type loudspeaker apparatus for reproducing sound in the bass range increases the size of the apparatus. Therefore, in its practical use, the horn is bent in its midsection or the apparatus is located at the corner of a room. There have been many enthusiasts for the horn-type loudspeaker because the loudspeaker has excellent transient characteristics and can produce clear basses. Although the horn-type loudspeaker apparatus can produce clear basses, it cannot produce all range of sounds from bass to treble by equally adjusting the distance from the sound source of the loudspeaker apparatus to a listener. The horn-type loudspeaker apparatus is generally applied to reproduction of midrange sounds, while a direct emission type loudspeaker apparatus to reproduction of bass range sounds.

It is important for the multiway loudspeaker system that the sound source positions are aligned to be in phase among the loudspeaker apparatuses for reproducing the sound range as much as possible for flattening sound pressure characteristics near a crossover frequency with respective to each apparatus. In the multiway loudspeaker system assembled with the horn-type and the direct emission type loudspeaker apparatuses, problems arise such that when the loudspeaker apparatuses are stacked in the vertical direction to align their sound source positions, the front part of the horn-type loudspeaker apparatus protrudes from the front surface of the direct emission type bass loudspeaker apparatus and the multiway loudspeaker system lacks uniformity in the appearance and becomes awkward. Furthermore, there are problems that the emitted sounds from the bass loudspeaker apparatus reflect at the horn of the midrange loudspeaker apparatus resulting in deterioration of the sound pressure characteristics and the tone of the bass loudspeaker apparatus.

Therefore, the conventional multiway loudspeaker system has had a priority to solve the above problems over the alignment of sound sources in case of using the horn type and the direct emission type loudspeaker apparatuses and attained the uniformity of the apparatuses by locating the sound source position of the direct emission type loudspeaker apparatus in front of that of the horn-type midrange loudspeaker apparatus. Furthermore, the conventional apparatus as disclosed in JP-A-Hei 5-130689, for example, has intended to flatten the sound pressure characteristic near the crossover frequency by setting the difference in the sound source positions to be the multiples of a wavelength of the crossover frequency to permit a phase lag and filtering it with a dividing network at a high attenuation factor.

However, the conventional multiway loudspeaker system as described above cannot improve the phase lag caused by the difference in the sound source positions and further produces an electrical phase lag by forced filtering with the dividing network. Such effects may not be clearly observed on measurement with continuous waves in a laboratory, but such effect can be happened in the actual audio reproduction where the waveforms vary in complexity every moment.

When the multiway loudspeaker system is constructed using the horn-type midrange loudspeaker apparatus and the direct emission type bass loudspeaker apparatus, a problem arises from either of the unity in appearance or in acoustics.

### SUMMARY OF THE INVENTION

But, a horn-type midbass loudspeaker apparatus with the corn-type loudspeaker can be used to properly reproduce up to the range of about 150 Hz with the sound source positions aligned. There exist two forms of the horn-type midbass loudspeaker apparatuses, the other having a diaphragm as the vibrator and a sound passage of 1 to 2 meters long from a throat to an opening and the other having a corn-type unit as the vibrator and a sound passage of 20 to 50 centimeters long. The present invention is intended to provide a latter bass loudspeaker apparatus capable of unifying in both appearance and acoustics and to provide a multiway loudspeaker system having the bass loudspeaker apparatus to solve the above problems. The “midbass loudspeaker apparatus having a corn-type unit as the vibrator” used with the bass loudspeaker apparatus of the present invention is hereinafter referred to as a “horn-type midbass” for distinguishing from the form having a diaphragm as the vibrator.

To solve the above problems, the inventor made a trial model of the bass loudspeaker apparatus having the cabinet shape capable of unifying in the appearance and acoustics of the horn-type midbass, and studied the frequency characteristics. As a result, the inventor found that when the apparatus is shaped so as to produce resonance called a “cavity effect” in the front section of the corn-type woofer at a specific frequency range, distortion in the frequency characteristic by the cavity effect can be corrected easily by filtering with a dividing network.

The “cavity effect” herein is described as a phenomenon in which an air spring in the depression and an air mass around the periphery of an opening of the depression produce resonance when a depression is in a flat part. It is known that a peak is formed in the frequency characteristic of the loudspeaker apparatus by the cavity effect when the front of a loudspeaker unit such as a corn-type woofer is enclosed from all directions to form a cavity inside. However, the cavity effect is not produced when the opening of the cavity is formed larger than the depth thereof, and the cavity functions as a horn to change the frequency characteristic into different form.

As described above, enclosing the front of the loudspeaker unit in all directions and forming a cavity cause the disorder of the frequency characteristic of the loudspeaker apparatus. Thus, placing the loudspeaker unit in the depth of the cabinet and forming a cavity in the front of the loudspeaker unit as described below are usually considered as an out-of-rule in the design of the cabinet.

It is an object of the present invention to provide a bass loudspeaker apparatus that generally aligns its sound source position in the longitudinal direction with that of the horn-type midbass as a midbass loudspeaker apparatus in the appearance and defines the shape of the resonant chamber formed in the front section of the corn-type woofer and a sound emission opening such that the distortion in the frequency characteristic produced in the resonant chamber is easily corrected by the filtering with a dividing network.

According to a first aspect of the present invention, there is provided a bass loudspeaker apparatus for a multiway loudspeaker system, comprising: a cabinet having an inner space and a sound emission opening in a front section; a corn-type woofer disposed within the cabinet; a baffle plate having a woofer mounting section and vertically disposed in the inner space so as to face the sound emission opening; a resonant chamber defined in front of the baffle plate for communicating with the sound emission opening; the resonant chamber and the sound emission opening being respectively designed such that resonance occurs between an air mass around the periphery of the sound emission opening and an air spring within the resonant chamber at a predetermined frequency range of 150 through 400 Hz, and the bass loudspeaker apparatus being connected to a dividing network for canceling out the intension of sound pressure by the resonance at the frequency range of the resonance.

That is, disposing the corn-type woofer in depth on the baffle plate mounted in the inner space of the cabinet and forming the resonant chamber so as to enclose the front of the corn-type woofer allows the approximate alignment of the front end of the horn-type midbass with that of the bass loudspeaker apparatus in the state that the sound source position of the bass loudspeaker apparatus is aligned with that of the horn-type midbass. Thus, the unity in the appearance is secured, as well as the acoustic wave emitted from the sound emission opening does not reflect to the horn of the horn-type midbass or the cabinet, and therefore the problems in the appearance is solved.

The followings are the reasons for enabling to correct the frequency characteristic change according to the cavity effect easily by a filter circuit. An ordinary bass loudspeaker apparatus attenuates sound pressure with a high-cut filter in the filter circuit based on that the determined crossover frequency is to be from −3 to −6 dB.

However, the bass loudspeaker apparatus of the present invention attenuates sound pressure with the high-cut filter to cancel out the rise of the peak from the frequency approximately one octave lower than the reference of the determined crossover frequency, that is, from the point where the peak of the frequency characteristic starts to be produced by the cavity effect. An effect of the intention of the sound pressure by the cavity effect from the start of the peak to the top of the peak is cancelled out by the attenuation of the high-cut filter, and the frequency characteristic of the bass loudspeaker apparatus is approximately flattened.

The sound pressure is sharply attenuated at the frequency exceeding the peak by the attenuation according to the cavity effect and the attenuation effect of the high-cut filter. Filtering with the dividing network corrects the frequency characteristic so as to flatten at the resonance frequency or less by the cavity effect and to cause a sharp attenuation at unnecessary mid-high range exceeding the resonance frequency. Accordingly, the bass loudspeaker apparatus of the present invention can easily correct the change in the frequency characteristic by the resonant chamber in the front section of the corn-type woofer with a high-cut filter of the dividing network and can accord with the horn-type midbass in both appearance and acoustics by defining the resonance frequency as the range within 150 through 400 Hz that can cross over to the horn-type midbass.

The horn-type mid-high range loudspeaker apparatus having a conventional diaphragm as the vibrator for reproducing the higher range than the reproduction range of the horn-type midbass has the same distance from the vibrator to the opening of the horn as the horn-type midbass and can be easily aligned its sound source position to that of the horn-type midbass in the longitudinal direction. The multiway loudspeaker system for attaining unity in the appearance as well as the acoustics can be constructed when the sound source of the bass loudspeaker apparatus of the present invention is aligned with those of the horn-type midbass and the conventional horn-type mid-high range loudspeaker apparatus in the longitudinal direction and the loudspeaker units of the loudspeaker apparatuses are respectively connected to the dividing network.

The resonance frequency by the cavity effect is determined according to the volume of the resonant chamber and the area of the sound emission opening, so that the frequency allowing the crossover can be changed by the correction of the size of the resonant chamber and the area of the sound emission opening. Therefore, combination of the different forms with the horn-type midbass is possible.

For the cavity effect, the frequency for producing the effect decreases and its intension increases as the depth of the resonant chamber gets deeper, and the frequency for producing the effect increases and its intension decreases as the depth of the resonant chamber becomes shallower. The frequency of 150 Hz or less makes the effect strong but to lose a balance with other loudspeaker apparatuses, and the frequency of 400 Hz or greater makes the effect weak and less attractive. In the frequency range between 150 and 400 Hz, the sound pressure intension effect by the cavity effect, the attenuation effect on the sound pressure by the dividing network for canceling out the intension effect, the frequency bands of the horn-type midbass and respective loudspeaker apparatuses, and the sound source positions of the bass loudspeaker apparatus and the respective loudspeaker apparatuses are properly related and interact.

The present invention can attain unity with the horn-type midbass in appearance and acoustics with the sound source position aligned and can provide a multiway loudspeaker system for attaining unity with the loudspeaker apparatuses in appearance and acoustics by using horn-type loudspeaker apparatuses for reproducing mid-high range or higher.

The bass loudspeaker apparatus of the present invention can attenuate sharply the frequency characteristic even if the attenuation factor of the dividing network is low and can cross over to the horn-type midbass with one element type (−6 dB/oct) dividing network.

In order to have a proper correlation, it is preferable that the depth of the resonant chamber for the bass loudspeaker apparatus, that is, the distance from the vibrator to the sound emission opening is between 10 and 40 centimeters. For example, when the horn-type midbass using the corn-type loudspeaker apparatus having a standard 30 cm diameter and the bass loudspeaker apparatus is crossed over, their sound source positions are approximately aligned in the longitudinal direction. The position of the vibrator is about 30 cm from the opening in each loudspeaker apparatus in case of the crossover at 200 Hz and about 20 centimeters in case of the crossover at 300 Hz, and the sound source positions of the horn-type midbass and the bass loudspeaker apparatus are aligned with respect to each other. The “depth” here is the shortest distance from the center of the vibrator to the sound emission opening of the corn-type woofer. When multiple corn-type woofers are disposed in the inner space of the cabinet, it is preferable that an average of the shortest distances from the vibrators to the sound emission openings of the corn-type woofers is in the range.

When the positions are not aligned and the range of error is small, the sound pressure around the crossover frequency can be flattened by the correction of the area of the sound emission opening and the dividing network. However, when the range of error cannot be corrected, the diameter of the corn-type loudspeaker apparatus may be changed to 25 centimeters, double loudspeaker apparatuses of 25 centimeters diameter may be used, or the size of the resonant chamber and the area of the sound emission opening may be modified.

According to the bass loudspeaker apparatus of the present invention, when the cavity effect is properly corrected by the dividing network, the attenuation factor of the sound pressure near the crossover frequency indicates sharper than the filtering inclination of the filter by the synergistic effect with the cavity effect. Although the filtering inclination of the high-cut filter in the dividing network corresponds to the inclination at the peak of the frequency characteristic by the cavity effect, the rising inclination is mostly in the range of 4 to 10 dB/oct when the size of the cabinet is in the normal range. Therefore, the cavity effect is properly corrected with one element type (−6 dB/oct) high-cut filter. When it cannot be corrected properly, the intension and the frequency of the cavity effect is changed and corrected by the correction of the ratio of the depth of the resonant chamber to the area of the sound emission opening.

Although one element type high-cut filter having a gentle filtering inclination is used, the attenuation factor near the crossover frequency in the frequency characteristic after the correction becomes significantly sharper than −6 dB/oct in synergy with the cavity effect.

Therefore, the present invention can have a shape according with the appearance of the horn-type midbass and easily define the resonance frequency of the resonant chamber to the range of 150 to 400 Hz.

It is considered to apply various methods for attenuating the midrange to the resonant chamber so as to further improve the frequency characteristic of the bass loudspeaker apparatus. For example, it is suggested in the present invention that the corn-type woofer is slanted in the cabinet facing the forward direction so as to attenuate unnecessary mid-high range in emitted sounds of the corn-type woofer by acoustic interference in the resonant chamber. In such the construction, the emitted sounds from the upper part and the lower part of the corn-type woofer have a phase lag and reflect at the inner wall of the resonant chamber, and therefore the emitted sounds and the reflected sounds with different phase interfere with each other. A low-frequency emitted sound with a long wavelength has a small phase lag, and therefore the attenuation of the sound pressure by the interference is small, and only the mid-high range part with a short wavelength is attenuated by the interference effect.

While the attenuation effect on the mid-high range is better as the inclination angle of the corn-type woofer is larger, if the inclination angle is excessively increased, the tone or emission efficiency of the sound is impaired. In the trial model, good results are obtained in the angle range between 50 and 70 degrees. Because the inclination of the corn-type woofer causes a phase lag in the right and left sounds, the corn-type woofer may be inclined in the horizontal direction and mounted off center on one side of the baffle plate.

The present invention can prevent the deterioration of the sound quality due to the mixing of unnecessary mid-high range part in emitted sounds form the corn-type woofer to midbass range in the emitted sounds from the horn-type midbass and properly cross over the bass loudspeaker apparatus to the horn-type midbass.

The baffle plate disposed within the inner space of the cabinet may be include not only a single corn-type woofer but also a plurality of corn-type woofers. In such the bass loudspeaker apparatus, plural corn-type woofers respectively have different sound source positions, and therefore emitted sounds from the corn-type woofers interfere with each other in the resonant chamber to attenuate the mid-high range part of each corn-type woofer properly. In such the construction, when the emitting direction of each corn-type woofer is slanted to the front section of the cabinet, the attenuation effect on the mid-high range can be improved more.

When multiple corn-type woofers are mounted in the inner space of the cabinet as described above, the multiple corn-type woofers may be mounted on one baffle plate. In addition, multiple baffle plates on the different longitudinal and horizontal position in the inner space may be disposed vertically to face the sound emission opening, and each of the corn-type woofers may be mounted on the separate baffle plate. While a large number of the corn-type woofers to be mounted increase the sound source positions and thus the attenuation factor for unnecessary mid-high range increases due to the interference of the emitted sounds from the each corn-type woofer in the resonant chamber, it is preferable that the number of the corn-type woofers is determined as two to six in the preferable embodiment.

The present invention can therefore cross over to the horn-type midbass since the emitted sounds from the corn-type woofers interfere with each other in the resonant chamber and the sound pressure of the unnecessary mid-high range is attenuated.

The present invention may further include a Helmholtz resonator disposed in an inner wall of the resonant chamber as an acoustical material for attenuating unnecessary specific bandwidth. In such the construction, the Helmholtz resonator has a high selectivity for the sound absorption frequency, and therefore, unnecessary bandwidth to be attenuated can be selectively controlled when the Helmholtz resonator according to the frequency characteristics of the corn-type woofer and the resonant chamber is disposed. It is more effective when felt as the acoustical material is used together.

While a closed cabinet can be used for the bass loudspeaker apparatus of the present invention, a bass reflex type apparatus can also be used when a bass reflex duct is disposed to pass through the baffle plate, to protrude to the back chamber formed in the backside of the cabinet, and to communicate the resonant chamber to the back chamber.

The present invention can selectively absorb the specific frequency range and therefore can control the unnecessary emitted sounds from the corn-type woofer effectively.

According to a second aspect of the present invention, there is provided not only a single bass loudspeaker apparatus but also a multiway loudspeaker system, including: a bass loudspeaker apparatus of the first aspect; a horn-type midbass loudspeaker apparatus including: a horn having approximately the same length as the depth of the resonant chamber in the bass loudspeaker apparatus, and a corn-type unit as a driver mounted so as to correspond the position of its sound source with that of the bass loudspeaker apparatus in a longitudinal direction; and a dividing network for allowing both of the loudspeaker apparatuses to cross over at the range of 150 through 400 Hz and canceling out the intension of sound pressure by the resonance in the resonant chamber of the bass loudspeaker apparatus at the frequency range of the resonance. Accordingly, the multiway loudspeaker system is provided in combination of the horn-type midbass according with the above bass loudspeaker apparatus in the appearance and acoustics and the dividing network. The multiway loudspeaker system can attain unity with the size of each apparatus and the cabinet.

Thus, the present invention can provide a horn-type loudspeaker apparatus and a bass loudspeaker apparatus according with each other in the appearance and acoustics and can reproduce smooth and continuous sounds with characteristic tones of the horn and clear bass with the multiway loudspeaker system having a unified appearance. The present invention can also improve the uniformity of the multiway loudspeaker system when the cabinet for the bass loudspeaker apparatus, the midbass and mid-high range loudspeaker apparatuses, and other apparatuses.

### BRIEF DESCRIPTION OF THE DRAWINGS

FIG. 1 is a perspective view showing a multiway loudspeaker system 100 having a bass loudspeaker apparatus A.

FIG. 2 is a right cross-sectional view of the multiway loudspeaker system 100.

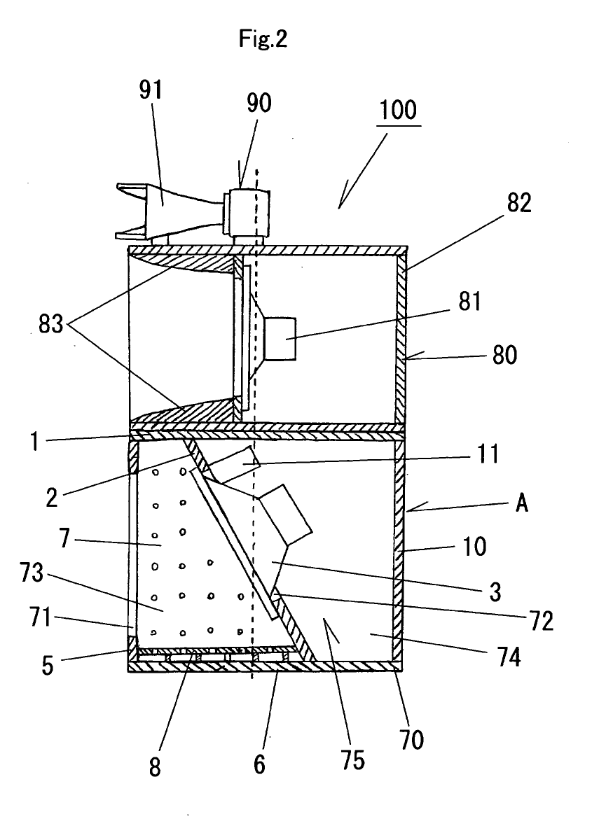

FIG. 3 is a line chart of the frequency characteristic of the bass loudspeaker apparatus A, in which the frequency characteristic of a comparison apparatus A′ is shown by a dashed line.

FIG. 4 is a line chart of the frequency characteristic of the bass loudspeaker apparatus A when the mid-high range is attenuated with a one-element type dividing network, in which the frequency characteristic of a comparison apparatus A′ is shown by a dashed line.

FIG. 5 is a right cross-sectional view of a bass loudspeaker apparatus B.

FIG. 6 is a line chart of the frequency characteristic of the bass loudspeaker apparatus B when the mid-high range is attenuated with a one-element type dividing network.

FIG. 7 is a right cross-sectional view of a bass loudspeaker apparatus C.

FIG. 8 is a right cross-sectional view of a bass loudspeaker apparatus D.

FIG. 9 is a perspective view showing the arrangement of corn-type woofers 42 when the outer housing of a cabinet 70d is transparent.

### DETAILED DESCRIPTION OF THE INVENTION

Embodiments of the present invention will be described with reference to the attached drawings.

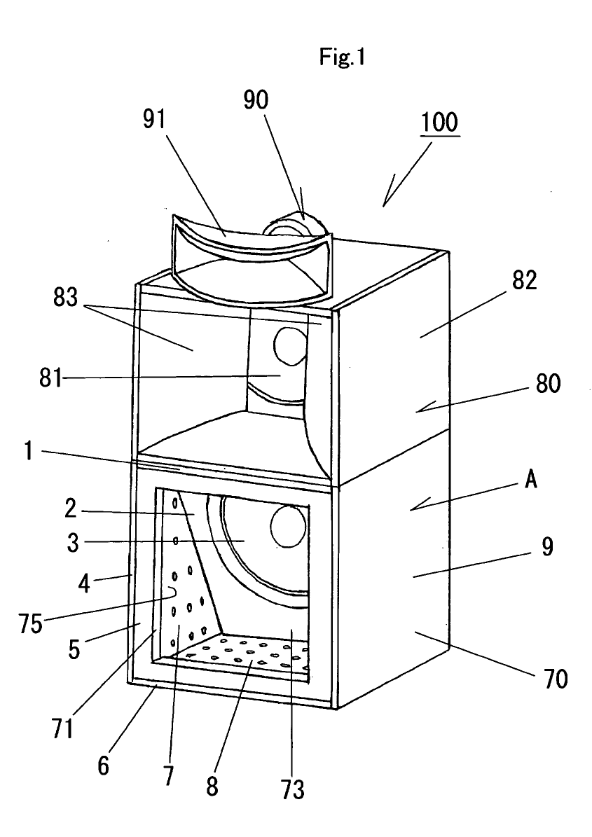

FIG. 1 shows a bass loudspeaker apparatus A according to the first embodiment. A horn-type midbass 80 is provided above the bass loudspeaker apparatus A and with a horn 83 in front of a corn-type loudspeaker apparatus 81, and a horn-type mid-high range loudspeaker apparatus 90 is further provided above those apparatuses. A multiway loudspeaker system 100 is constructed with respective loudspeaker apparatuses A, 80, and 90 and a dividing network (not shown) for connecting those apparatuses.

In this multiway loudspeaker system 100, the dividing network divides an input signal into three bands and outputs to respective loudspeaker apparatuses A, 80, and 90. The mid-high range loudspeaker apparatus 90 then reproduces the frequency band of about 800 Hz or greater, the horn-type midbass 80 reproduces 200-800 Hz, and the bass loudspeaker apparatus A of the present invention reproduces 200 Hz or less. The bass loudspeaker apparatus A is arranged such that the position of its sound source mutually corresponds to that of the horn-type midbass 80 and the mid-high range loudspeaker apparatus 90 in the longitudinal direction. The loudspeaker apparatuses A, 80, and 90 of this embodiment have one loudspeaker unit, respectively, and therefore the position of the sound source approximately corresponds to the condition that the longitudinal position of diaphragms is aligned.

Regarding the structure of the bass loudspeaker apparatus A, the bass loudspeaker apparatus A is provided with a corn-type woofer 3 and a cabinet 70 for housing the corn-type woofer 3. The conventional woofer can be used for such corn-type woofer 3. The size of the cabinet 70 may be defined by the shape or characteristic of the corn-type woofer 3. The cabinet 70 is assembled with the sheets of plywood to form a cubical box having an inner space 75 and a rectangular sound emission opening 71 in the front section. In the inner space 75, a baffle plate 2 is vertically disposed to face the sound emission opening 71 and divide the inner space 75 into a resonant chamber 73 in the front side and a back chamber 74 in the back side. A circular woofer mounting section 72 is formed in the center of the baffle plate 2, and the corn-type woofer 3 is mounted on the mounting section 72 to direct the emitting direction toward the sound emission opening 71. The baffle plate 2 is disposed to slant to the front at the elevation angle of 60 degrees and to cause the emitting direction of the corn-type woofer 3 to slant forward and downwardly at 30°.

In proximity to the woofer mounting section 72, a bass reflex duct 11 is disposed to pass through the baffle plate 2 and to connect the resonant chamber 73 with the back chamber 74, and thus the bass part in the emitted sounds from the back side of the corn-type woofer 3 is supplied to the front side to decrease bass reproduction limit frequencies in the bass loudspeaker apparatus A.

The baffle plate 2 is disposed in the inner space 75 such that the depth of the resonant chamber 73 or the distance from the center of the diaphragm of the corn-type woofer 3 to the sound emission opening 71 is 30 cm. The depth of the resonant chamber 73 is applied approximately 30 cm to the horn length of the horn-type midbass 80 used in the present invention. Respective positions of the front ends of the loudspeaker apparatuses A, 80, and 90 generally coincide with each other in the condition that the sound source positions of the apparatuses are aligned as described above, and therefore the multiway loudspeaker system 100 is integrally formed in the appearance.

Description will now be made of the structure of the resonant chamber 73 as an essential part of this embodiment.

The resonant chamber 73 is designed in such a shape that an air mass around the periphery of the sound emission opening 71 and an air spring within the resonant chamber resonate at approximately 200 Hz. The resonance frequency of the resonant chamber 73 is generally determined by the area of the sound emission opening 71 and the volume of the resonant chamber73, but the depth or width of the resonant chamber 73 is defined to the shape in accord with the loudspeaker apparatuses 80 and 90 to be used with. Therefore, the resonance frequency of the resonant chamber 73 is adjusted by the area of the sound emission opening 71 and defined to be 200 Hz.

Due to the form of the cabinet 70 and the characteristics of the corn-type woofer 3, when the return of the “cavity effect” becomes large and a high sound pressure part is generated in the range of 600 Hz to 1 kHz, Helmholtz resonators 7 and 8 using felt or other materials is attached to the side panel 4 and the bottom panel 6 constituting the inner wall of the resonant chamber 73 in order to selectively absorb the unnecessary high sound pressure part in midrange.

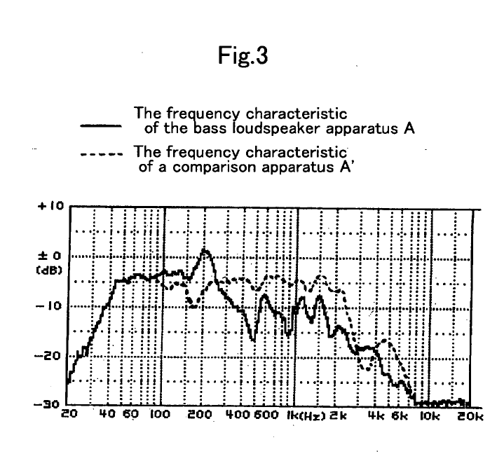

FIG. 3 shows frequency characteristics of the bass loudspeaker apparatus A according to the present invention and a comparison apparatus A′. The comparison apparatus A′ is provided with the same corn-type woofer 3 as the bass loudspeaker apparatus A and a back chamber having the same volume as that of the back chamber 74 of the bass loudspeaker apparatus A and is a direct emission type bass loudspeaker apparatus which nothing is formed in the front surface of the corn-type woofer 3.

The comparison apparatus A′ with the above structure has a generally flat frequency characteristic in the range of 50 Hz to 2 kHz approximately. On the contrary, the bass loudspeaker apparatus A produces nearly identical sound pressure with the comparison apparatus A′ at frequencies of about 90 Hz or less; however, the sound pressure increases at frequencies exceeding 90 Hz and reaches the maximum around 200 Hz. The sound pressure then starts to decrease after the frequency passes 200 Hz, becomes the same level as the comparison apparatus A′ at 250 Hz, continues to drop, and reaches the minimum value at 500 Hz. This “wave” means the cavity effect of the resonant chamber 73. In the mid-high range after the cavity effect, the sound pressure remains at the level 6 dB less than that of the comparison apparatus A′. The decrease in the sound pressure is mainly caused by the interference effect from the slanting of the corn-type woofer 3 to the front part of the cabinet 70.

As described above, the bass loudspeaker apparatus A of this embodiment has similar characteristics to the comparison apparatus A′ at frequencies of about 90 Hz or less, but exhibits the intension by the cavity effect in the range of 90 Hz to 250 Hz and the decrease of the sound pressure caused by the cavity effect and the interference sound absorption effect at unnecessary 250 Hz or greater.

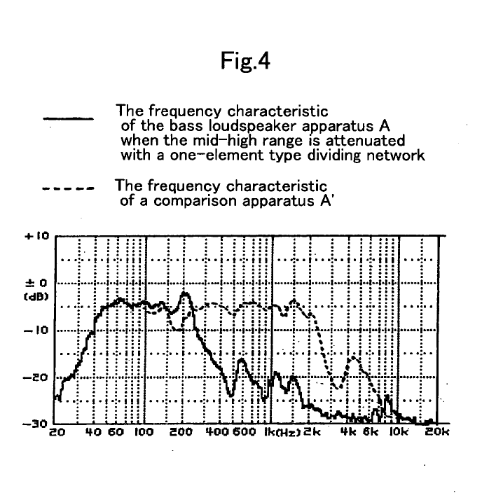

FIG. 4 shows frequency characteristics of the bass loudspeaker apparatus A in the attenuation of the midrange by the electrical load of the dividing network. The sound pressure is attenuated by filtering with a high cut filter of one-element type (−6 dB/oct) from 90 Hz where the intension of the sound pressure by the cavity effect is exhibited. In such the frequency characteristic, the sound pressure exhibits nearly flat level from 50 Hz to 200 Hz and is attenuated with a sharp decline at the frequency exceeding 200 Hz.

Such frequency characteristic becomes flat in the frequency range of 90 to 200 Hz as the intension of the sound pressure by the cavity effect is canceled out due to the attenuation of the sound pressure by the high cut filter. Then, when the frequency exceeds the resonance frequency of 200 Hz, rapid attenuation of the sound pressure arises from the attenuation by the cavity effect of the resonant chamber 73 combined with the attenuation effect of the dividing network.

As described above, the bass loudspeaker apparatus A of this embodiment is provided with the corn-type woofer 3 disposed in the depth of the inner space 75 of the cabinet 70 and forms the resonant chamber 73 producing resonance at a certain frequency in the front of the corn-type woofer 3. Thus, the bass loudspeaker apparatus A, the horn-type midbass 80, and the horn-type mid-high range loudspeaker apparatus 90 are assembled with their sound source positions aligned in the longitudinal direction and constitutes the multiway loudspeaker system 100 in accord with the appearances.

When the shape of the resonant chamber 73 is constructed as described above, distortion in the frequency characteristic of the resonant chamber 73 by the cavity effect is properly corrected with the dividing network, and the bass loudspeaker apparatus A properly crosses over to the horn-type midbass 80. Therefore, the acoustic conformity can be attained.

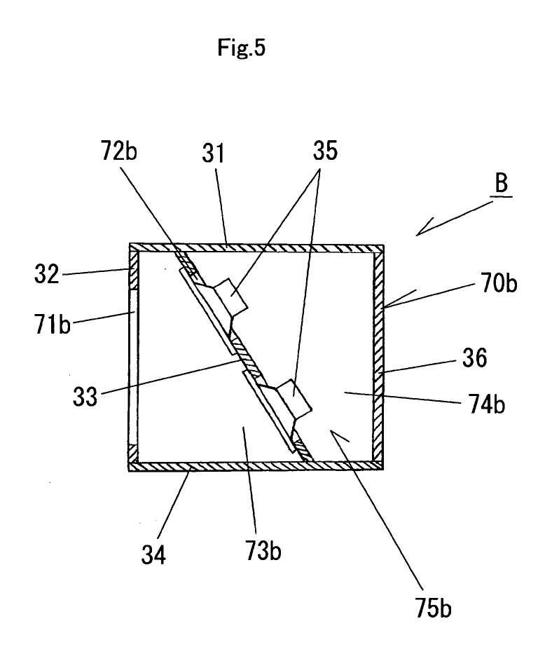

FIG. 5 shows a bass loudspeaker apparatus B according to the second embodiment, in which two corn-type woofers 35, 35 are mounted on the baffle plate 33 fixed in the inner space 75b of the cabinet 70b at the elevation angle of 60 degrees, displacing their positions in the longitudinal and vertical direction with respect to each other. In this embodiment, the resonant chamber 73b is formed such that the cavity effect occurs at the resonance frequency of approximately 200 Hz and the average depth is to be 30 centimeters. Other structures are the same as the bass loudspeaker apparatus A of the first embodiment, and therefore, the description of the common components will be omitted.

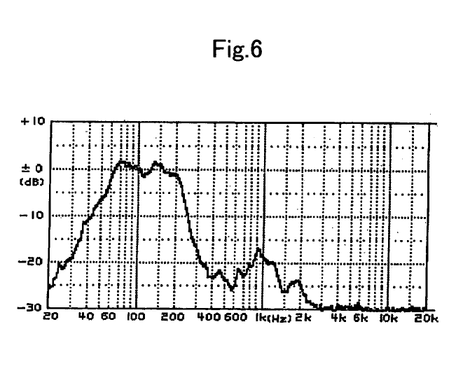

FIG. 6 shows a frequency characteristic when this bass loudspeaker apparatus B is connected with a one-element type dividing network to correct the peak of the frequency characteristic by the cavity effect. In this case, the frequency characteristic becomes flat at 60 to 200 Hz, and the sound pressure drops with large attenuation factor at the frequency exceeding 200 Hz. Since two corn-type woofers 35, 35 are disposed and multiple sound sources exist within the cabinet 70b, such large attenuation factor is assumed to be produced by the interference of the emitted sounds from the corn-type woofers 35, 35 within the entire resonant chamber 73b. As described above, the structure that a plurality of corn-type woofers 35 is mounted in the bass loudspeaker apparatus B can attenuate the sound pressure in the mid-high range very efficiently.

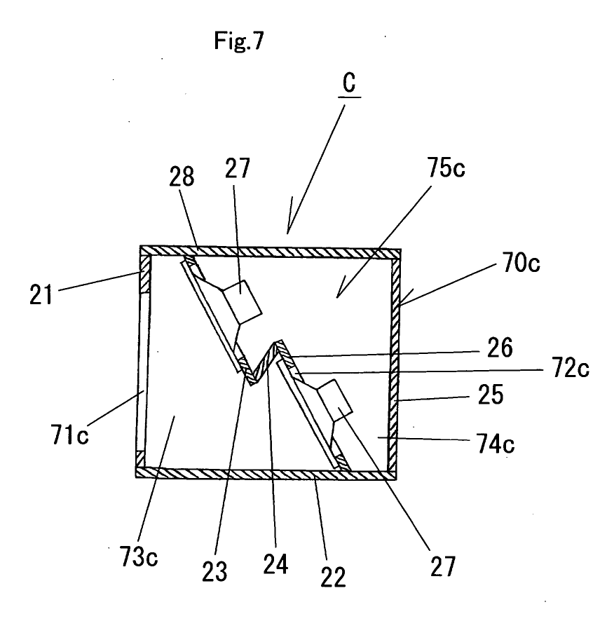

FIG. 7 shows a bass loudspeaker apparatus C according to the third embodiment, in which corn-type woofers 27 are mounted respectively on two upper and lower baffle plates 23 and 26 arranged to displace in the front and back sides within the inner space 75c of the cabinet 70c. In such the construction, the corn-type woofer 27 is not disposed on the same baffle plate as compared to the bass loudspeaker apparatus B of the second embodiment. Therefore, the corn-type woofer 27 having larger diameter can be mounted in proportion to the height of the cabinet 70c, or the height of the cabinet 70c can be reduced when the unit has the same diameter.

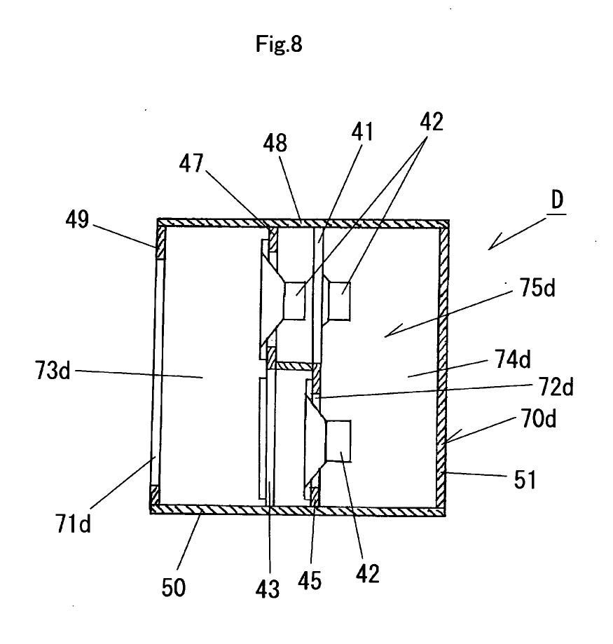

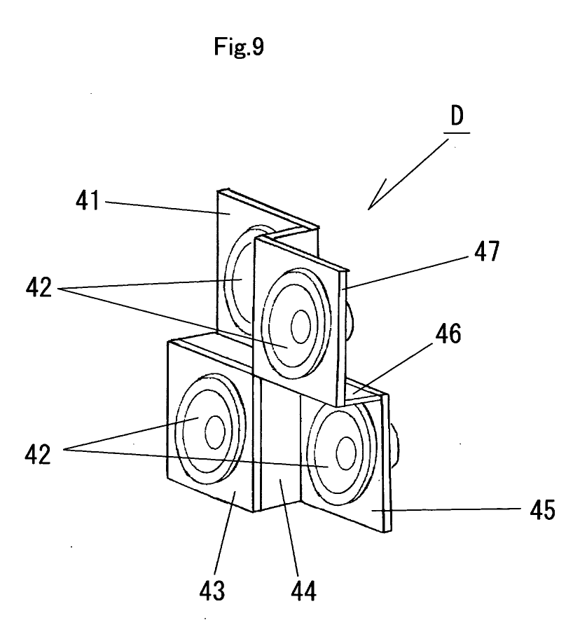

FIGS. 8 and 9 show a bass loudspeaker apparatus D according to the fourth embodiment, in which a resonant chamber 73d and a back chamber 74d are divided by four baffle plates 41, 43, 45, and 47 respectively arranged in the longitudinal, horizontal, and vertical positions within the inner space 75d of the cabinet 70d, and four uniform corn-type woofers 42 are respectively mounted on the baffle plates 41, 43, 45, and 47. Other structures are the same as the bass loudspeaker apparatus A of the first embodiment, and therefore, the description of the common components will be omitted. In such the construction, emitting directions of all the corn-type woofers 42 are directed toward the front side of the cabinet 70d, but the mounting positions of the corn-type woofers 42 are displaced in the longitudinal direction. Therefore, the emitted sounds cause interferential action with respect to each other, and the sound pressure in the mid-high range is attenuated.

While the present invention has been described to put into practice, it is understood that the present invention is not limited to the above embodiments and variations and modifications are possible without departing from the scope of the present invention.

For example, when multiple corn-type woofers are provided within the cabinet, those woofers may be slanted in the different directions. Furthermore, although electrical phase lag occurs even if the dividing network is replaced from the standard −6 dB/oct type to a −12 dB/oct or −18 dB/oct type, the present invention as described above can bring an improvement in enjoying music as compared to the conventional apparatus having large misalignment of the sound source position. The bass loudspeaker apparatus of the present invention can be made as a multiway loudspeaker in which the horn-type mid-high range loudspeaker apparatus is interposed in combination with the horn-type midbass and the loudspeakers are integrated as a vertical coaxial type.

What is claimed is:

1. A bass loudspeaker apparatus for a multiway loudspeaker system, comprising:
a cabinet having an inner space and a sound emission opening in a front section;
a corn-type woofer disposed within the cabinet;
a baffle plate having a woofer mounting section and vertically disposed in the inner space so as to face the sound emission opening;
a resonant chamber defined in front of the baffle plate for communicating with the sound emission opening;
the resonant chamber and the sound emission opening being respectively designed such that resonance occurs between an air mass around the periphery of the sound emission opening and an air spring within the resonant chamber at a predetermined frequency range of 150 through 400 Hz, and
the bass loudspeaker apparatus being connected to a dividing network for canceling out the intension of sound pressure produced by the resonance at the frequency range of the resonance.

2. The bass loudspeaker apparatus of claim 1, wherein the depth of the resonant chamber is between 10 and 40 cm.

3. The bass loudspeaker apparatus of claim 1, wherein the corn-type woofer is slanted in the cabinet facing the forward direction so as to attenuate unnecessary mid-high range in emitted sounds of the corn-type woofer by acoustic interference in the resonant chamber.

4. The bass loudspeaker apparatus of claim 1, wherein the baffle plate disposed within the inner space of the cabinet includes a plurality of corn-type woofers.

5. The bass loudspeaker apparatus of claim 1, further including a Helmholtz resonator which is disposed in an inner wall of the resonant chamber as an acoustical material for attenuating unnecessary specific bandwidth.

6. A multiway loudspeaker system, comprising:
a bass loudspeaker apparatus of claim 1;
a horn-type midbass loudspeaker apparatus including: a horn having approximately the same length as the depth of the resonant chamber in the bass loudspeaker apparatus; and a corn-type unit as a driver mounted so as to correspond the position of its sound source with that of the bass loudspeaker apparatus in a longitudinal direction; and
a dividing network for allowing both of the loudspeaker apparatuses to cross over at the range of 150 through 400 Hz and canceling out the intension of sound pressure by the resonance in the resonant chamber of the bass loudspeaker apparatus at the frequency range of the resonance.
